(19) United States
(12) Patent Application Publication
(10) Pub. No.: US 2026/0287681 A1
(43) Pub. Date: Sep. 24, 2026

(54) ELECTRICAL DIAGNOSTICS USING POWERFLOW LOAD TESTING SYSTEMS AND APPARATUSES

(71) Applicant: Power Probe Group, Inc., Charlotte, NC (US)

(72) Inventor: David Douglas Barden, Crestline, CA (US)

(73) Assignee: Power Probe Group, Inc., Charlotte, NC (US)

(21) Appl. No.: 19/408,992

(22) Filed: Dec. 4, 2025

Related U.S. Application Data
(60) Provisional application No. 63/773,686, filed on Mar. 18, 2025.

(51) Int. Cl. G01R 31/58

(52) U.S. Cl. CPC G01R 31/58

(57) ABSTRACT

Systems, apparatuses, and kits for testing integrity of a wire use a method that includes testing, via a voltage testing module of an electrical diagnostic device, an unloaded voltage of the wire, and receiving a selection indicating whether the wire is to be tested via a positive load test or a negative load test. A resistive load is applied to the wire and upon application of the resistive load a loaded voltage of the wire is tested. The tested unloaded voltage is compared, via processor(s) of the electrical diagnostic device, to the tested loaded voltage to determine whether a voltage change exists. Based on comparing the voltage change to a predetermined threshold, whether the integrity of the wire is compromised is determined and an indication of whether the integrity of the wire is compromised is displayed via a user interface of the electrical diagnostic device.

### CROSS REFERENCE TO RELATED APPLICATIONS

The present application claims priority benefit of U.S. Provisional Patent Application No. 63/773,686, entitled ELECTRICAL DIAGNOSTICS USING POWERFLOW LOAD TESTING SYSTEMS AND APPARATUSES filed on March 18, 2025, the entire contents of which are expressly incorporated by reference herein. In addition, the present application incorporates by reference in their entireties U.S. Patent No. 7,184,899 filed January 5, 2005, entitled ENERGIZABLE ELECTRICAL TEST DEVICE FOR MEASURING CURRENT AND RESISTANCE OF AN ELECTRICAL CIRCUIT and U.S. Patent No. 6,356,853 filed December 27, 1999, entitled ENHANCING VOLTMETER FUNCTIONALITY.

### FIELD OF THE INVENTION

This invention relates generally to the field of electrical diagnostic systems and devices, and more particularly, systems and devices for testing integrity of a wire.

### BACKGROUND OF THE INVENTION

Electrical diagnostics on electrical components of vehicles can be time consuming and labor intensive. As vehicles become more technologically advanced to incorporate additional electrical circuitry, the potential for failure of electrical components can become more prevalent. Troubleshooting and diagnosing problems with such electrical systems requires the use of a wide array of complex test equipment. Such test equipment may include, for example, devices commonly referred to as multimeters and which are configured to measure resistance, voltage, and current and more. Other diagnostic testing that is typically performed on motor vehicle electrical systems includes logic probes which measure and detect the presence and polarity of voltages as well as determining the continuity in electrical circuits. Often there are several different devices being used to measure or test electrical circuits, and technicians have to make certain judgment calls that rely on experience and industry knowledge in order to accurately diagnose a problem.

For example, in electrical diagnostics, technicians may evaluate whether a wire is working by taking a voltage reading or other measurement using, for example, a multimeter. Testing the voltage may indicate that the voltage reads as expected; however, the voltage read may not stay the same when that wire is expected to carry a current to a load. Thus, existing devices, systems, and methods intended to provide electrical diagnostics have various shortcomings. Accordingly, a need exists to provide improved vehicle diagnostic devices, systems and methods.

### BRIEF SUMMARY

Shortcomings of the prior art are overcome and additional advantages are provided through the provision of an electrical diagnostic method for testing integrity of a wire. The method includes testing, via a voltage testing module of an electrical diagnostic device, an unloaded voltage of the wire, receiving a selection indicating whether the wire is to be tested via a positive load test or a negative load test, and applying a resistive load to the wire. Further, upon application of the resistive load, a loaded voltage of the wire is tested. The method also includes comparing, via one or more processors of the electrical diagnostic device, the tested unloaded voltage to the tested loaded voltage to determine whether a voltage change exists, determining, based on comparing the voltage change to a predetermined threshold, whether the integrity of the wire is compromised, and displaying, via a user interface of the electrical diagnostic device, an indication of whether the integrity of the wire is compromised.

Also disclosed herein is a system for electrical diagnostics. The system includes an electrical diagnostic device, electrical connectivity wiring to electrically couple to the electrical diagnostic device to a power source, and a probe tip to be electrically coupled to the electrical diagnostic device and to contact a wire to be tested. Further, the electrical diagnostic device includes, a processor and a memory device storing executable code. When executed, the executable code causes the processor to test, via a voltage testing module and while the probe tip is in contact with the wire, an unloaded voltage of the wire, receive a selection indicating whether the wire is to be tested via a positive load test or a negative load test, apply a resistive load to the wire, test, upon application of the resistive load, a loaded voltage of the wire, compare the tested unloaded voltage to the tested loaded voltage to determine whether a voltage change exists, determine, based on comparing the voltage change to a predetermined threshold, whether the integrity of the wire is compromised, and display, via a user interface of the electrical diagnostic device, an indication of whether the integrity of the wire is compromised.

An electrical diagnostic apparatus for testing wire integrity is also disclosed. The apparatus includes at least one processor, a user interface communicatively coupled to the at least one processor, a voltage testing module configured to test voltage of a wire, a load testing module, a voltage comparison module, and a memory device storing executable code. When executed, the executable code causes the at least one processor to test, via the voltage testing module and while the probe tip is in contact with the wire, an unloaded voltage of the wire, receive a selection indicating whether the wire is to be tested via a positive load test or a negative load test, apply, via the load testing module, a resistive load to the wire, test, upon application of the resistive load, a loaded voltage of the wire, compare, via the voltage comparison module, the tested unloaded voltage to the tested loaded voltage to determine whether a voltage change exists, determine, based on comparing the voltage change to a predetermined threshold, whether the integrity of the wire is compromised, and display, via the user interface of the electrical diagnostic device, an indication of whether the integrity of the wire is compromised.

An electrical diagnostic kit is also disclosed that includes an electrical diagnostic device, electrical connectivity wiring to electrically couple to the electrical diagnostic device to a power source, a probe tip to be electrically coupled to the electrical diagnostic device and to contact a wire to be tested, and an auxiliary ground lead. Further, the electrical diagnostic device includes a processor and a memory device storing executable code. When executed, the executable code causes the processor to test, via a voltage testing module and while the probe tip is in contact with the wire, an unloaded voltage of the wire, receive a selection indicating whether the wire is to be tested via a positive load test or a negative load test, apply a resistive load to the wire, test, upon application of the resistive load, a loaded voltage of the wire, compare the tested unloaded voltage to the tested loaded voltage to determine whether a voltage change exists, determine, based on comparing the voltage change to a predetermined threshold, whether the integrity of the wire is compromised, and display, via a user interface of the electrical diagnostic device, an indication of whether the integrity of the wire is compromised.

Additional features and advantages are realized through the concepts described herein.

### BRIEF DESCRIPTION OF THE DRAWINGS

One or more aspects are particularly pointed out and distinctly claimed as examples in the claims at the conclusion of the specification. The foregoing as well as objects, features, and advantages of one or more aspects are apparent from the following detailed description taken in conjunction with the accompanying drawings in which:

FIG. 1 depicts a block diagram of an electrical test device and illustrates a power supply, a microprocessor, a display device, a keypad, load test circuitry, and a probe element, according to one embodiment;

FIG. 2A illustrates a front view of an example electrical diagnostic device, according to one embodiment;

FIG. 2B illustrates a back view of the example electrical diagnostic device of FIG. 2A;

FIG. 3 illustrates an example circuit testing diagram, according to one embodiment; and

FIG. 4 depicts a block diagram of an example method, according to one embodiment.

### DETAILED DESCRIPTION

Aspects of the present invention and certain features, advantages, and details thereof are explained more fully below with reference to the non-limiting examples illustrated in the accompanying drawings. It is to be understood that the disclosed embodiments are merely illustrative of the present invention and the invention may take various forms. Further, the figures are not necessarily drawn to scale, as some features may be exaggerated to show details of particular components. Thus, specific structural and functional details illustrated herein are not to be interpreted as limiting, but merely as a representative basis for teaching one skilled in the art to employ the present invention.

Descriptions of well-known processing techniques, systems, components, etc. may be omitted to not unnecessarily obscure the invention in detail. It should be understood that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure. Additionally, numerous inventive aspects and features are disclosed herein, and unless inconsistent, each disclosed aspect or feature is combinable with any other disclosed aspect or feature as desired for a particular embodiment of the concepts disclosed herein.

The specification may include references to “one embodiment”, “an embodiment”, “various embodiments”, “one or more embodiments”, etc. may indicate that the embodiment(s) described may include a particular feature, structure or characteristic, but every embodiment may not necessarily include the particular feature, structure, or characteristic. In some cases, such phrases are not necessarily referencing the same embodiment. When a particular feature, structure, or characteristic is described in connection with an embodiment, such description can be combined with features, structures, or characteristics described in connection with other embodiments, regardless of whether such combinations are explicitly described.

The terms “couple,” “coupled,” “couples,” “coupling,” and the like should be broadly understood to refer to connecting two or more elements or signals electrically and/or mechanically, either directly or indirectly through intervening circuitry and/or elements. Two or more electrical elements may be electrically coupled, either direct or indirectly, but not be mechanically coupled; two or more mechanical elements may be mechanically coupled, either direct or indirectly, but not be electrically coupled; two or more electrical elements may be mechanically coupled, directly or indirectly, but not be electrically coupled. Coupling (whether only mechanical, only electrical, or both) may be for any length of time, e.g., permanent or semi-permanent or only for an instant. Additionally, “electrically coupled” and the like should be broadly understood and include coupling involving any electrical signal, whether a power signal, a data signal, and/or other types or combinations of electrical signals.

In addition, as used herein, the terms “about,” “approximately,” or “substantially” for any numerical values or ranges indicate a suitable dimensional tolerance that allows the device, part, or collection of components to function for its intended purpose as described herein. As used herein, the term “vehicle” is to be interpreted broadly to include any machine used to transport people or cargo including, for example, motor vehicles (e.g., motorcycles, cars, trucks, buses, mobility scooters, etc.), railed vehicles (e.g., trains, trams, etc.), watercraft (e.g., ships, boats, underwater vehicles, etc.), amphibious vehicles (e.g., hovercraft, screw-propelled vehicles, etc.), aircraft (e.g., airplanes, helicopters, etc.), and spacecraft.

Disclosed herein are example apparatuses, systems and methods for probing a trouble circuit or wire to determine whether a voltage drop is within an acceptable threshold range. Further, the apparatuses, systems and methods also perform additional functions central to electrical diagnostics. For example, the apparatuses disclosed herein may be specifically adapted to provide current sourcing to an electrical system while also providing multi-meter functionality for selective measurement of a plurality of parameters of the electrical system. The apparatuses, systems, and methods may be uniquely configured to allow for the collection of data on active, even on relatively high-current, electrical systems. Further, the apparatuses, systems, and methods allow access to current flow through the electrical system and includes the capability to characterize loaded impedance, wave form (e.g., fluctuation, frequency/speed), and current drain in addition to functions commonly performed by multi-meters such as voltage, current and resistance measurements.

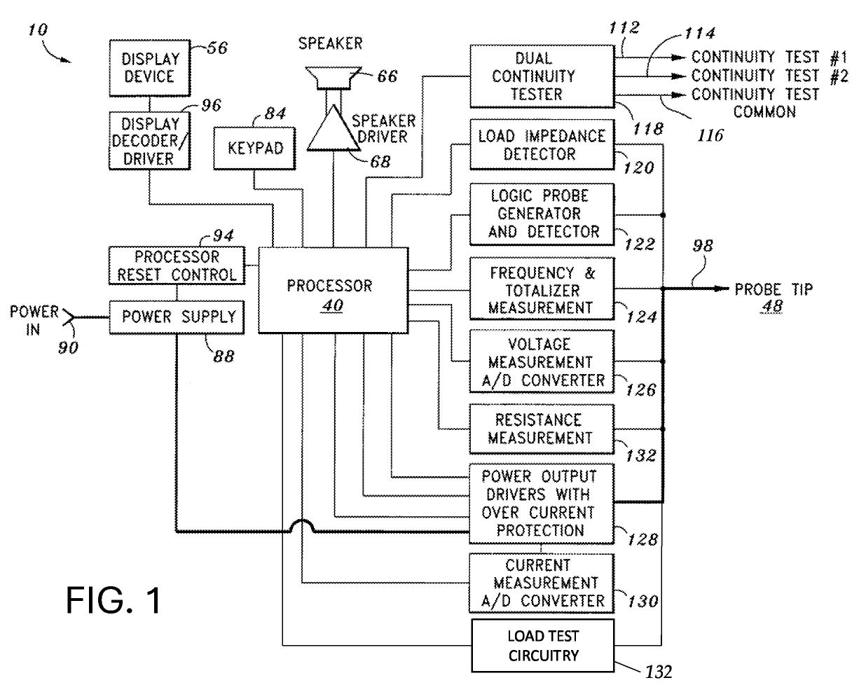

FIG. 1 depicts a block diagram of an electrical test device 10 and illustrates a power supply 88, a microprocessor 40, a display device 56, a keypad 84, load test circuitry 132, and a probe element 48. Although each of the functional blocks is indicated as a separate block, componentry may be shared therebetween for facilitating any particular measurement of the electrical system.

In one embodiment, the electrical test device 10 is configured to allow for selective powering of the electrical system under test upon energization of the probe element 48 while parameters of the electrical system are being measured. With reference to FIG. 1, many of the functional blocks may be under control of the processor 40 (e.g., a microprocessor). Further, the conductive probe element 48 may be configured to be placed into contact with an electrical system in order to test a wire or circuit. In one embodiment, the conductor probe element 48 is configured to provide an input signal to the electrical system. The power supply 88 is interconnected between an external power source 90 and the probe element 48. The power source 90 may be configured as a battery of a vehicle, and the electrical system being tested may be the electrical system of that same vehicle. However, the external power source 90 may be configured in a variety of embodiments other than a motor vehicle battery and could represent another type of battery or other source of power if, for example, the wire or circuit being tested is at a testing bench or outside of the vehicle environment. The power supply 88 may be connected to a processor reset control 94 such as a microprocessor reset control 94. The microprocessor reset control 94 may include circuitry that provides a reset signal to the processor 92 or microprocessor 40 under conditions where the operating voltage may be out of tolerance. The power supply 88 may be configured to provide a voltage regulated output for all circuitry within the electrical test device 10. The voltage regulated output is provided independent of any input signal to the electrical system under test. The microprocessor reset control 94 is electrically connected to the processor 40 or microprocessor 40. The processor 40 or microprocessor 40 is electrically connected to the probe element 48 and is configured to manipulate the input signal provided to the electrical system and to receive an output signal in response to the input signal. The output signal is representative of the testing or measurement of at least one of the parameters of the electrical system. In manipulating and controlling the electrical test device 10 measurement functions, the processor 40 or microprocessor 40 may be provided with an executable software program configured to provide control of the various measurement processes of the electrical test device 10. In this manner, the processor 40 or microprocessor 40 controls all the functions of the electrical test device 10.

The electrical test device 10 includes a display device 56 which is electrically connected to the processor 40 or microprocessor 40 and which is configured to display a reading of the output signal which is extracted from the electrical system under test. The reading is representative of the parameter being tested or measured. It should also be noted that an audible device may be included within the electrical test device 10 for providing an audible indication of certain operating parameters of the electrical system under test. For example, the audible device may comprise a piezo element such as a piezo disk which acts as a speaker 66 for providing information regarding continuity measurements and voltage polarity of the electrical system. As was earlier mentioned, the electrical test device 10 is specifically configured to allow for selective powering of the electrical system upon energization of the probe element 48 during testing or measurement of the parameters of the electrical system. The electrical device may be configured to automatically switch between one of an active mode and a passive mode wherein the active mode is defined by testing or measurement of the parameters of the electrical system during powering thereof. As was previously mentioned, such power is ultimately supplied by an external power source 90 and which is directed through a power supply 88 and passed into the probe element 48. In this manner, the probe element 48 may transfer current into the electrical system under test. The passive mode is defined by testing or measurement of the parameters of the electrical system without the application of power to the electrical system being tested. The application of power may be controlled by a keypad 84 as being connected to a processor 40 or microprocessor 40. In some embodiments, the keypad 84 may include a toggle switch located on the front face of the electrical test device 10 and/or the keypad 84 may include one or more buttons or a toggle switch located on the back face of the electrical test device 10.

In addition, the display device 56 such as a liquid crystal display may be operative to indicate whether the test device 10 is in the passive mode or the active mode. The electrical test device 10 may include a speaker driver 68 which is connected to the speaker 66 (i.e., the piezo element) and which handles the formatting and converting of signals from the processor 40 or microprocessor 40 such that the speaker 66 may be operated as necessary. In the same sense, the display driver 96, shown as being connected between the processor 40 or microprocessor 40 and the display device 56, is also operative to format and convert signals from the processor 40 or microprocessor 40 into a format needed for display by the display device 56. The electrical test device 10 also includes a dual continuity tester 118, load impedance detector 120, logic probe detector and generator 122, frequency and totalizer measurement 124, voltage measurement 126, resistance measurement 132, power output driver 128 with over current protection, current measurement 130, and load test circuitry 132.

The voltage measurement 126 functionality and the current measurement 130 functionality may each include analog-to-digital conversion mechanisms. The electrical test device 10 can simultaneously measure current and voltage of the electrical system being tested due to the application of current sourcing into the electrical system under test by way of the external power source 90. The dual continuity tester 118 functionality block may be used in conjunction with the current source provide by the probe when energized by the power supply 88. The operation of the dual continuity tester 118 of the electrical test device 10 in combination with its signal lamps provides for an extremely convenient means for testing the functionality of multi-pole relays. More specifically, the dual continuity tester 118 is configured to allow testing of multiple contacts with the pressing of a single button of the electrical test device wherein the coil resistance of the relay may be easily measured. The electrical test device 10 may measure and display average voltage as well as measurement and display of positive peak voltage and negative peak voltage. Importantly, the measurement of negative peak voltage enhances the ability to analyze and measure voltage of an alternator having a faulty diode.

The dual continuity tester 118, when coupled with the measurement functions of the electrical test device 10, enables testing of contact switches in relay devices. For example, in an electrical system having two relays, the dual continuity tester 118 provides for the capability to determine which one of the two relays is activated and/or which is deactivated. In this manner, the dual continuity tester 118 allows for checking of relays using a pair of signal lamps. When testing relays or switches in this manner, the speaker 66 is preferably configured to be inoperative to avoid producing audible signals that may otherwise impede detection of noises that are indicative of a functioning switch. Both the signal lamp and/or the audible device may be used to provide an indication as to the activated or deactivated state of the relays. Furthermore, the dual continuity tester 118 may be used to check the status and operability of multiple contacts such as in a multi-pole/multi-contact relay or switch. In order to test continuity, an auxiliary cable may be inserted into or otherwise protrude from an auxiliary jack of the electrical test device 10, and the first continuity test lead 112, a second continuity test lead 114, and continuity test common ground 116 may be connected to the electrical system under test. In the active mode, wherein power is supplied to the electrical system under test, the continuity of a particular portion of the electrical system may be verified by using the auxiliary cable comprising the first continuity test lead 112 and/or the second continuity test lead 114 in combination with the continuity test common ground 116.

The load impedance detector 120 functional block allows for measurement of the magnitude of a voltage drop such as when testing electrical junctions in an electrical circuit. The load impedance detector 120 functional block is useful in testing power feed circuits that may have loose or corroded connections. As will be described in greater detail below, when the probe element 50 is connected to the electrical system under test, the impedance of the electrical system may be tested and the electrical test device 10 may provide an indication, either audibly via the speaker 66 and/or visually via the display device 56 (i.e., the liquid crystal display (LCD)) such as when a set point (i.e., a predetermined voltage level) is above a specified voltage limit.

The logic probe generator and detector 122 functional block comprises a circuit that creates a sequence for outputting into a device of the electrical system under test through the probe element 48. For example, a digital pulse train may be inputted into a device of the electrical system with the digital pulse train inserted into a terminal of a device under test in order to assess communication between components of the electrical system (e.g., between an odometer in communication with a control unit of a motor vehicle). The logic probe generator and detector 122 functionality also provides the electrical test device 10 with a capability to measure signal levels as well as frequency. High and low logic levels may be generated as well as pulse trains at various frequencies.

The frequency and totalizer measurement 124 functional block allows the electrical test device 10 to assess the rate of voltage or current fluctuation in the electrical system under test, and to accumulate occurrences of a particular state over time. Circuitry of the frequency and totalizer measurement 124 block allow for processing of signal transition of a waveform in order to extract the frequency, revolutions per minute (RPM), duty cycle and number of pulses from a signal. The frequency aspect of the frequency and totalizer measurement 124 functional block allows for determining the frequency or RPM or duty cycle component of the electrical system. The totalizer aspect of the frequency and totalizer measurement 124 functional block accumulates pulses or cycles and allows the electrical test device 10 to measure and check for intermittent output signals from the electrical system under test. The frequency and totalizer measurement 124 functional block also provides a means for checking switches in an electrical system by providing a means for measuring the number of times that a contact within a switch bounces, for example, such as may occur in a relay switch. The frequency and totalizer measurement 124 functionality allows for measuring signals from the electrical system as well as providing the capability for entering a “divide ratio”, which may be equivalent to the number of cylinders of an engine within the motor vehicle being tested. In this manner, the electrical test device 10 may measure the revolutionary speed at which a motor vehicle engine is operating. In addition, as was previously discussed, rates of voltage or current fluctuation may be measured and signal transition components of a wave form may be analyzed to extract frequency, duty cycle and number of pulses.

The voltage measurement 126 block allows for measurement of high-speed voltage in the electrical system. The voltage measurement 126 block represents the ability of the electrical test device 10 to sample and detect positive and negative peaks of a signal as well as detecting and measuring an average of the signals and displaying results of the signal readout on the display device 56. The voltage measurement 126 block simplifies voltage drop tests, voltage transient tests and voltage fluctuation or ripple tests. The power output driver 128 with over current protection functional block provides a buffer stage or a transistor for the electrical test device 10 such that the power output driver 128 with over current protection regulates the amount of current that may be passed from the power supply 88 to the probe element 48 and ultimately into the electrical system under test. In addition, the power output driver may establish an appropriate drive impedance and protect the electrical test device 10 from damage due to automotive transients. The current measurement 130 functional block allows for high-speed current measurement 130 by the electrical test device 10 such that sampling and detection of current consumed in a load provided in the input signal which is passed into the electrical system. Such consumed current may be displayed on the display device 56.

According to one embodiment, a printed circuit board assembly (PCBA) may be housed within the electrical test device 10 and may be interconnected with the processor 40 or microprocessor 40, display device 56, power supply 88, reset control 94, speaker driver 68, and display driver 96. Further the PCBA may be electrically coupled to the power source 90 and the probe element 48. The PCBA may include at least one fuse, and in some cases multiple fuses that provide a safety mechanism to prevent damage to the circuitry of the electrical test device 10. The electrical test device 10 may also include a circuit breaker, which may have configurable trip levels, and provide for a manual circuit breaker reset. The PCBA may also have the piezo element integrated therewith to facilitate audio transmission.

In addition, the keypad 84 may allow for the configuration of measuring and displaying various parameters of AC voltage and DC voltage measurements, resistance of the electrical circuit, current flowing within the electrical circuit, the frequency of signals, etc. More specifically, the electrical test device 10 may be manipulated such that parameters measurable by the electrical test device 10 include at least one of the following: circuit continuity, resistance, voltage, current, load impedance, and frequency, RPM and pulse counting. In addition, further measurement modes may be facilitated through manipulation of the keypad 84. For example, frequency, RPM, duty cycle and totalizer measurements may be provided upon an electrical circuit in a test. In addition, signal level and frequency may be measured as well as testing of impedance.

Load impedance detection functionality may be facilitated such that the magnitude of a voltage drop within an electrical system such as when testing electrical junctions in power feed circuits that may have loose or corroded connections. The electrical system under test may be measured with differences there between being assessed and displayed on the display device 56. The logic probe generator and detection functional block, as was previously discussed, allows for testing for high logic, low logic and pulsing logic signals. The electrical test device 10 is configured to allow forcing of a signal into the electrical system under test with manipulation of multiple functions of the logic detection functionality such that an appropriate input signal may be injected into the electrical system under test

The electrical test device 10 may be manipulated such that parameters testable or measurable by the electrical test device 10 include at least one of the following: circuit continuity, resistance, voltage, current, load impedance, and frequency, RPM, pulse counting, and voltage change in response to a resistive load being applied. In the active mode, where power is supplied to the electrical system under test, the continuity of a particular portion of the electrical system may be verified. Load impedance detection functionality may be facilitated such that the magnitude of a voltage drop within an electrical system being tested such as when testing electrical junctions in power feed circuits that may have loose or corroded connections.

The electrical test device 10 may be operated as a digital voltmeter capable of performing a voltage drop test and battery load testing as well as transient voltage testing. In addition, the combination of the power output drivers 128 with current measurement 130 capability allows the electrical test device 10 to measure current and voltage simultaneously. The electrical test device 10 may be placed in the active mode and can be placed in a “latched” or permanent operation mode, where a constant supply of power is provided through the conductive probe element 48 into the electrical system under test. However, the electrical test device 10 can be placed in a “momentary” power mode wherein power may be supplied on an as-requested basis due to manual manipulation of one or more buttons of the electrical test device 10.

The processor 40 or microprocessor 40 may be configured to cause periodic energization of the probe element 48 for powering the electrical system under test at predetermined intervals. The electrical system may include, for example, an electromechanical device. Examples of electromechanical devices that may be tested in this manner include, but are not limited to, relay switches, solenoids, motors and various other devices. Power may be provided to the electrical system under test on an automatic intermittent basis at predetermined intervals such as, for example, at one-second intervals. Advantageously, the ability to provide power in such varying modes allows for testing the proper operation of electro-mechanical devices such as relay switches as well as in tracing locations of such electro-mechanical devices. By connecting the electrical test device 10 to the external power source 90 and intermittently providing current into the electrical system through the probe element 48, a user may more easily track the location of a faulty relay switch by listening for a clicking sound as power is intermittently applied thereto. Such method for checking for faulty relay switches may be especially valuable in detecting a relay switch that may be hidden underneath carpeting, seating and/or plastic molding commonly found in automotive interiors.

The load test circuitry 132 may include a test load such as a load, resistor, resistive load, emulated resistive load, or other form of resistance. The load test circuitry 132 may provide a load in the electrical system under test when current is flowing through the electrical system. The load test circuitry 132 may be used to apply a resistive load to the electrical system under test in response to selection, via keypad 84 (e.g., which may include button(s) and or toggle(s) positioned on the front face or back face of the electrical test device 10, of a positive load test or a negative load test.

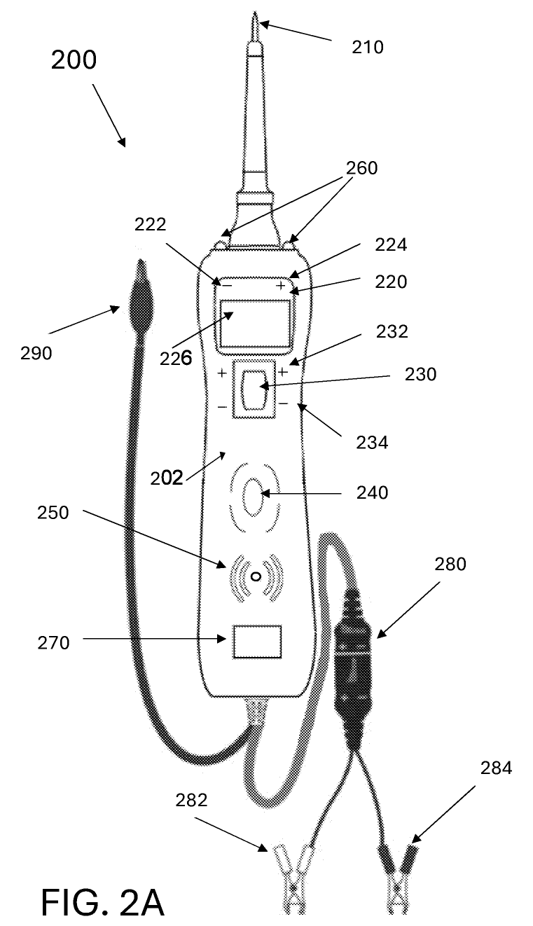

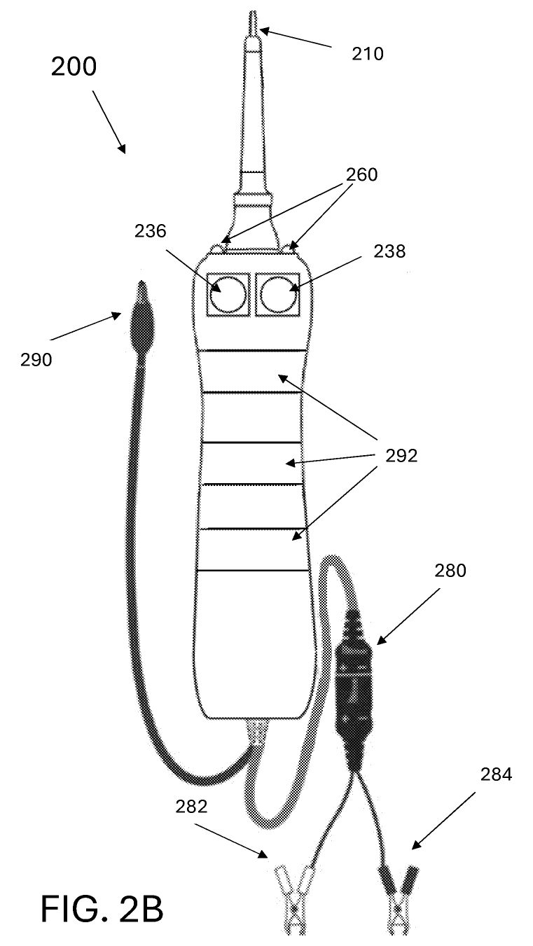

FIGS. 2A-2B illustrate an example electrical diagnostic device 200, according to one embodiment. The electrical diagnostic device 200 may include a housing 202 configured as a generally elongated encasement that protects the PCBA. The housing 202 has a top end that includes a probe element (e.g., such as probe element 48 described above with reference to FIG. 1) with a probe tip 210 extending therefrom that is configured to be in contact with the electrical system under test. The probe tip 210 may be a 4 mm removable tip. Opposite the top end of the housing 202 is a bottom end that has a bushing extending therefrom that may have a ground lead 290 extending therefrom that forms a constant ground and alligator clips 282, 284 for connecting to a power source such as a car battery. The alligator clips 282, 284 may be coupled to a switch 280 that when closed will allow for current flow between the alligator clips 282, 284 and the electrical diagnostic device 200. The electrical diagnostic device 200 may include lights 260 to illuminate the work area. Pressing the rocker switch 230 forward towards the positive direction 232 can provide a circuit breaker protected power to the probe tip 210 and rearward towards the negative direction 234 provides a ground connection to the probe tip 210. It is also envisioned that rather than having alligator clips 282, 284, some embodiments may incorporate an automobile auxiliary power outlet that is sized and shaped or otherwise configured to plug into a 12 V accessory socket of a car.

The electrical diagnostic device 200 includes a user interface 220 with a red light 224 for indicating a positive polarity for when the rocker switch 230 is pressed toward the positive direction 232 and a green light 222 for when the rocker switch 230 is pressed toward the negative direction 234. The user interface 220 of the electrical diagnostic device 200 may also include an LCD display 226 for providing a visual indication of various parameters being tested or measured. The electrical diagnostic device 200 also includes a circuit breaker reset button (not shown) that may be disposed on the side of the housing 202. Optionally, the electrical diagnostic device 200 may also include an indicator 270 that indicates a model of the electrical diagnostic device 200. The backside shell of the housing 202 may also include ridges 292 to provide better grip to the electrical diagnostic device 200.

The electrical diagnostic device 200 may also include a mode button 240, which can be used to turn audio on and off and to cycle through various modes. For example, the mode button 240 can be used to a first mode to test or otherwise measure an average voltage level of an electrical system under test, a second mode referred to as a “negative peak mode” to monitor a positive electrical system under test and test or otherwise measure the lowest voltage, a third mode referred to herein as a “positive peak mode” that captures the highest detected voltage of an electrical system under test, a fourth mode referred to herein as a “peak to peak” mode that measures the difference between the positive and negative peak voltage levels over a predetermined time period, a fifth mode that provides a threshold level setting to adjust the threshold voltage while performing the “peak to peak” measurement or the average voltage level, and a sixth mode referred to herein as a “load test” mode to test an electrical circuit under load. The electrical diagnostic device 200 may also include speaker holes 250 that are formed in the shell of the housing 202 to allow for transmission of audible tones generated by the piezo disk, which may occur during transition through the various modes by selecting the mode button 240. For example, different audio tones may be emitted when switching through the selectable modes. If the audio is turned on, a speaker may appear on the LCD display 226.

During the first mode where the average voltage level is determined, the red light 224 or green light 222 may provide an indication on polarity and an audio tone will also be emitted that indicates whether the electrical system under test is positive or negative. For example, a lower tone (i.e., a low beep sound) may indicate the electrical system under test is negative whereas a relatively higher tone (i.e., a high beep sound) may indicate the electrical system is positive. The second mode may be activated when the mode button 240 is selected for more than a predetermined time until a low-pitched beep is audible, and the LCD display 226 indicates a negative (minus) sign in the lower corner. The initial reading of the display in the second mode may initially read “0.0” because no voltage is present. Once the probe tip 210 is in contact with the positively charged electrical system to be tested, the mode button 240 may be selected once and the LCD display 226 will show the lowest detected voltage of the electrical system. During the third mode, the mode button 240 may be held for a predetermined time until a beep sound is emitted and the mode button 240 may be held again for another predetermined time until subsequent beep sounds are emitted until a quick high-pitched beep is emitted and the LCD display 226 indicates a positive (plus) sign. Prior to placing the probe tip 210 in contact with the electrical system, the LCD display 226 should have a reading of “0.0” and once the probe tip 210 is in contact with the electrical system it will display the highest voltage reading. The fourth mode is activated once the mode button 240 has been held for a predetermined time to get to the first mode, repeated again to get to the second mode, repeated a third time to get to the third mode, and repeated a fourth time to get to the fourth mode. During the fourth mode can be used to monitor the diode rectifier in a charging system while the engine of a vehicle is running in order to evaluate whether the diode rectifier is defective. The fifth mode is reached once the mode button 240 has been selected for several periods of time until an alternative positive (+) and negative (–) sign is present on the LCD display 226. The “peak to peak” threshold voltage setting loop incrementally from “0.2” to “0.5” to “1.0” to “2.0” to “5.0” to “10.0” to “50.0” and cycle back to “0.2” again with each selection of the mode button 240. Once the desired threshold voltage is identified, the mode button 240 may be pressed for a predetermined period of time until it beeps, which indicates the threshold voltage has been selected so that the threshold voltage can be used in one of the other modes (e.g., the first mode to measure the average voltage). The sixth mode or “load test” mode may be reached once the user has cycled through the appropriate number of predetermined time periods by selecting the mode button 240. The sixth mode may activate a voltage testing module to test an unloaded voltage and a loaded voltage of an electrical system. During operation, the user may select the appropriate load button 236, 238 or load rocker switch (not shown), based on whether the electrical system is to be tested via a positive load test or a negative load test, while toggling the rocker switch 230 to the positive directly 232 or negative direction 234.

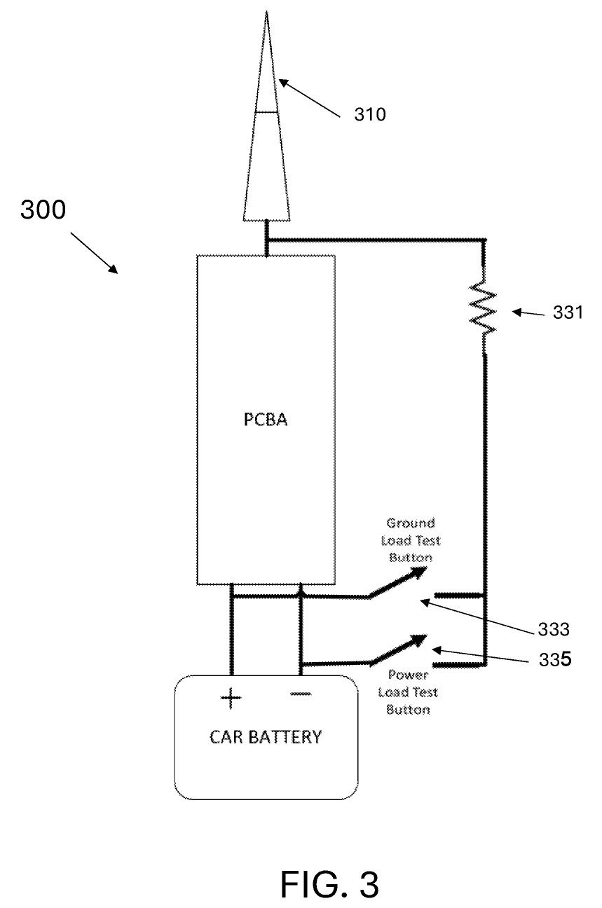

FIG. 3 illustrates an example circuit testing diagram 300, according to one embodiment. The load resistor 331 may be positioned between the probe tip 310 and the power and ground cables that are connected to the power source (e.g., the car battery). When the probe tip 310 is on the ground circuit, the “ground load” test button 333 (e.g., such as one of the buttons 236, 238 of FIG. 2B) may be selected in order to close the connection. Alternatively, when the probe tip 310 is on a power circuit, the “power load” test button 335 (e.g., such as one of the buttons 236, bof FIG. 2B) may be selected.

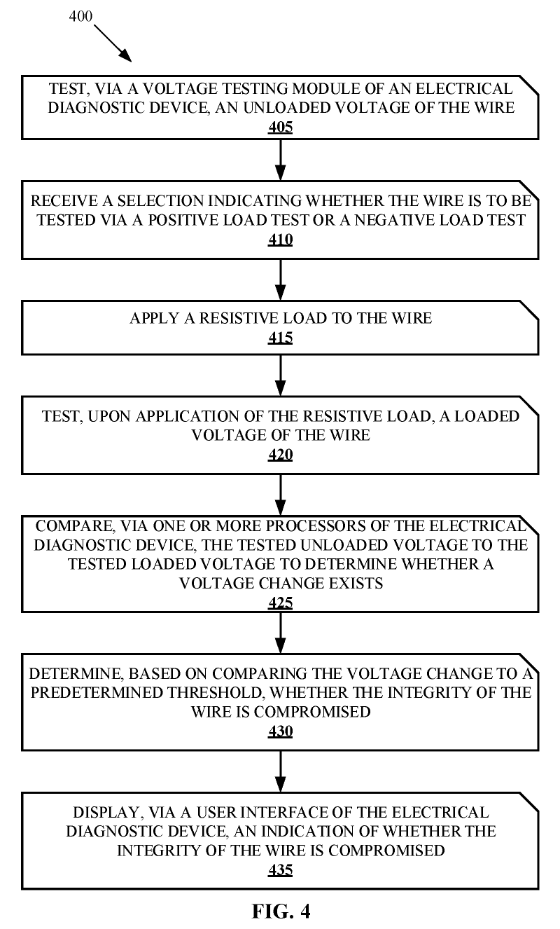

FIG. 4 depicts a block diagram of an example method 400, according to one embodiment. At block 405, the electrical diagnostic device may be used to test or otherwise measure, via a voltage testing module, an unloaded voltage of the wire. At block 410, the electrical diagnostic device may receive a selection indicating whether the wire is to be tested via a positive load test or a negative load test. When the wire is initially non-energized, and the selection indicates the wire is to be tested via the positive load test, the testing of the unloaded voltage includes inputting, via the electrical diagnostic device, voltage to the wire to energize the wire and the resistive load is applied simultaneously to the electrical diagnostic device inputting the voltage to the wire in order to perform the testing of the loaded voltage. Further, the voltage change for the positive load test is a voltage drop. In some embodiments, the wire is energized and based on the selection indicating the wire is to be tested via the negative load test the unloaded voltage of the wire is 0 V. Further, the indication of whether the integrity of the wire is compromised indicates confirmation the integrity of the wire is indeed compromised if the voltage change is different than the unloaded voltage due to the change to the predetermined threshold being 0 V.

In some embodiments, the unloaded voltage of the wire is tested upon completion of testing continuity of the wire, wherein testing the continuity of the wire indicates whether the wire is part of an open circuit or closed circuit. Further, the testing of the unloaded voltage of the wire is performed in response to the continuity testing resulting in an indication that the wire is part of the closed circuit. The indication that the wire is part of the closed circuit may be displayed, via the user interface, in response to an auxiliary ground clip of the electrical diagnostic device being connected to the wire, a first battery clip being connected to a positive terminal of a battery of a vehicle, a second battery clip being connected to a negative terminal of the battery, and a probe tip of the electrical diagnostic device being connected to the wire. In some embodiments, the testing of the unloaded voltage and the testing of the loaded voltage when the wire is part of the open circuit are non-functional.

At block 415, the electrical diagnostic device may apply a resistive load to the wire. This application is a passive application where the resistive load is applied based on the “ground load” test button or the “power load” test button being selected. At block 420, upon application of the resistive load, a loaded voltage of the wire is tested or otherwise measured. The loaded voltage to the wire may be input based on receiving an indication that a toggle switch located on a front face of the electrical diagnostic device has been toggled to a positive voltage and the resistive load is applied based on receiving a signal that a button located on a back face of the electrical diagnostic device has been selected, the button corresponding to the positive load test, the button being selected while the toggle switch has been toggled. In some embodiments, the button also includes another toggle switch. In some embodiments, the loaded voltage to the wire is input based on receiving an indication that a toggle switch located on a front face of the electrical diagnostic device has been toggled to a negative voltage and the resistive load is applied based on receiving a signal that a button located on a back face of the electrical diagnostic device has been selected, the button corresponding to the negative load test, the button being selected while the toggle switch has been toggled.

At block 425, the electrical diagnostic device may compare, via one or more processors, the tested unloaded voltage to the tested loaded voltage to determine whether a voltage change exists. At block 430, based on comparing the voltage change to a predetermine threshold, the electrical diagnostic device may determine whether the integrity of the wire is compromised. At block 435, the electrical diagnostic device displays, via a user interface, an indication of whether the integrity of the wire is compromised. This may be through means of a light, which may be accompanied by an auditory signal, or the user interface may indicate, via an LCD display, that the wire is compromised. Advantageously, this eliminates the need for the technician to calculate the voltage compared to the voltage drop and make a judgment call as to whether the drop in voltage sufficiently surpasses the expected voltage drop in order to render the wire compromised. In some embodiments, the predetermined threshold level corresponds to 1 volt.

In some embodiments, the testing of the unloaded voltage and the testing of the loaded voltage are performed while the electrical diagnostic device is electrically coupled to a battery of a vehicle. In various embodiments, the resistive load that is applied is performed using at least one resistor located within the electrical diagnostic device that passively draws current. In one example, the at least one resistor is a single 500 milliamp resistor.

In some embodiments, the method 400 also includes energizing, via the electrical diagnostic device, the wire, wherein a source of voltage energizing the wire is a battery and the current flows through the electrical diagnostic device in order to energize the wire. In addition, the unloaded voltage of the wire corresponds to the voltage of the battery. In some examples, the voltage of the battery is in the range from 11 volts to 25 volts. In some embodiments, the wire is between 10 gauges and 25 gauges.

The systems disclosed herein have several advantages over existing technology because it seamlessly allows for measuring positive side voltage drops or negative side voltage changes by switching whether the positive load test or negative load test is to be performed. There is no need to completely rewire or switch configurations or devices in order to perform the load testing process. There is no need to have a separate multimeter device or other external device and there are no manual calculations that would need to be performed. Rather, the disclosed systems and methods are programmed to perform the comparison between the unloaded voltage test and the loaded voltage test and evaluate whether the change in voltage exceeds a threshold amount, in which case an indication is provided that indicates whether the integrity of the wire is compromised. Further, the external battery, such as a car battery, powers the electrical diagnostic device so no additional battery internal to the device is needed. The electrical diagnostic device will easily allow a technician to identify whether it is a ground side wiring problem or a positive side wiring problem. Further, the device configuration allows a technician to test the wire with only a single hand by contacting the probe to the wire.

Referring back to FIGS. 2A and 2B, according to various embodiments, the electrical diagnostic device 200 may include a communication means for communicating with an external computing device (e.g., a laptop, desktop computer, mobile computing device (i.e., smartphone), portable digital assistant, pager, virtual assistance device such as a smart speaker or other smart home device, or any combination of the aforementioned, or other portable device with processing and communication capabilities). The electrical diagnostic device 200 may utilize, according to various embodiments, wired or wireless communication means. For instance, the apparatus 200 may include a radio-frequency transceiver to communicate via Bluetooth with the external computing device. In various embodiments, the electrical diagnostic device 200 may include a Bluetooth communication means (e.g., a Class 2 Bluetooth transceiver), a Wi-Fi communication means, a near-field communication means, and/or other transceivers. Alternatively, the apparatus may connect via a connection port for wired connections via USB, Ethernet, and/or other physically connected modes of data transfer.

In some embodiments, the electrical diagnostic device 200 may include a transmitter, receiver, transceiver, etc. and/or other communication interface (e.g., an antenna) that provides signals to and/or receives signals from the respective transmitter or receiver of the external computing device. According to one embodiment, the apparatus 550 may be configured to operate in accordance with various cellular communication protocols (e.g., second-generation (2G) wireless communication protocols, third-generation (3G) wireless communication protocols, fourth-generation (4G) wireless communication protocols, fifth-generation (5G) wireless communication protocols, and/or the like). In other embodiments, the apparatus 550 may be configured to operate in accordance with non-cellular communication mechanisms, such as via a wireless local area network (WLAN) or other communication data network.

According to various embodiments, the electrical diagnostic device 200 may communicate via a network, which may include more than one network without departing from the scope of these descriptions. In some embodiments, the network may be or provide one or more cloud-based services or operations. The network may be or include an enterprise or secured network, or may be implemented, at least in part, through one or more connections to the Internet. A portion of the network may be a virtual private network (VPN) or an Intranet. The network can include wired and wireless links, including, as non-limiting examples, 802.11a/b/g/n/ac, 802.20, WiMAX, LTE, and/or any other wireless link. The network may also include one or more local area networks (LANs), radio access networks (RANs), metropolitan area networks (MANs), wide area networks (WANs), personal area networks (PANs), WLANs, campus area network (CAN), metropolitan area network (MAN), storage-area network (SAN), all or a portion of the internet and/or any other communication system or systems at one or more locations. The network may include any internal or external network, networks, sub-network, and combinations of such operable to implement communications between various other computing components.

According to various embodiments, data may be stored, via a storage device (e.g., random access memory (RAM), read-only memory (ROM), volatile memory such as a cache area for temporary storage of data, non-volatile memory that is embedded and/or removable such as electrically erasable programmable read-only memory (EEPROM), flash memory, or the like).

According to various embodiments, an analyzer or other components of the PCBA may perform multiple functions including monitoring voltage and/or current. For instance, according to one embodiment, the sensor(s) (e.g., resistor(s)) may detect voltage drop across a resistor, and that voltage drop is then converted by the analyzer into a current value using Ohm’s law, thereby deriving current flow. According to one embodiment, the analyzer includes or otherwise utilizes an ammeter and/or a voltmeter. The ammeter may include, for example, at least a 0.001A resolution with the capacity to measure between 0A – 10A. Further, the voltmeter may include, for example, at least a 0.01V resolution with a capacity to measure between 0V – 30V.

Flowcharts and block diagrams depicted in the figures may illustrate functionality and operation of possible implementations of various apparatuses, systems, and methods, according to various embodiments of the present invention. In this regard, each block in the flowcharts and block diagrams may incorporate a specific function or portion of a function. Additionally, the flowcharts and block diagrams may incorporate alternative implementations and the functions noted in the block diagram may occur in a different order from that noted in the figures. For example, two blocks shown in succession may, in fact, be executed substantially concurrently, or the functions noted in the blocks may be implemented in reverse order depending on the functionality involved.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiments were chosen and described in order to best explain the principles of one or more aspects of the invention and the practical application, and to enable others of ordinary skill in the art to understand one or more aspects of the invention for various embodiments with various modifications as are suited to the particular use contemplated.

It is to be noted that various terms used herein such as “Bluetooth” and the like may be subject to trademark rights in various jurisdictions throughout the world and are used here only in reference to the products or services properly denominated by the marks to the extent that such trademark rights may exist.

What is claimed is:

1. A system for electrical diagnostics, the system comprising:
an electrical diagnostic device;
electrical connectivity wiring to electrically couple to the electrical diagnostic device to a power source; and
a probe tip to be electrically coupled to the electrical diagnostic device and to contact a wire to be tested;
wherein the electrical diagnostic device includes:
a processor; and
a memory device storing executable code that, when executed, causes the processor to:
test, via a voltage testing module and while the probe tip is in contact with the wire, an unloaded voltage of the wire;
receive a selection indicating whether the wire is to be tested via a positive load test or a negative load test;
apply a resistive load to the wire;
test, upon application of the resistive load, a loaded voltage of the wire;
compare the tested unloaded voltage to the tested loaded voltage to determine whether a voltage change exists;
determine, based on comparing the voltage change to a predetermined threshold, whether the integrity of the wire is compromised; and
display, via a user interface of the electrical diagnostic device, an indication of whether the integrity of the wire is compromised.

2. The system of claim 1, wherein the wire is initially non-energized and based on the selection indicating the wire is to be tested via the positive load test the testing of the unloaded voltage includes inputting, via the electrical diagnostic device, voltage to the wire to energize the wire and the resistive load is applied simultaneously to the electrical diagnostic device inputting the voltage to the wire in order to perform the testing of the loaded voltage.

3. The system of claim 2, wherein the voltage change for the positive load test is a voltage drop.

4. The system of claim 2, wherein the loaded voltage to the wire is input based on receiving an indication that a toggle switch located on a front face of the electrical diagnostic device has been toggled to a positive voltage and the resistive load is applied based on receiving a signal that a button located on a back face of the electrical diagnostic device has been selected, the button corresponding to the positive load test, the button being selected while the toggle switch has been toggled.

5. The system of claim 1, wherein the wire is energized and based on the selection indicating the wire is to be tested via the negative load test the unloaded voltage of the wire is 0 V.

6. The system of claim 5, wherein the indication of whether the integrity of the wire is compromised indicates confirmation the integrity of the wire is compromised based on the voltage change being different than the unloaded voltage due to the change to the predetermined threshold being the 0 V.

7. The system of claim 5, wherein the loaded voltage to the wire is input based on receiving an indication that a toggle switch located on a front face of the electrical diagnostic device has been toggled to a negative voltage and the resistive load is applied based on receiving a signal that a button located on a back face of the electrical diagnostic device has been selected, the button corresponding to the negative load test, the button being selected while the toggle switch has been toggled.

8. The system of claim 5, wherein the unloaded voltage of the wire is tested upon completion of testing continuity of the wire, wherein testing the continuity of the wire indicates whether the wire is part of an open circuit or closed circuit.

9. The system of claim 1, wherein the testing of the unloaded voltage and the testing of the loaded voltage are performed while the electrical diagnostic device is electrically coupled to a battery of a vehicle.

10. An electrical diagnostic apparatus for testing wire integrity, the apparatus comprising:
at least one processor;
a user interface communicatively coupled to the at least one processor;
a voltage testing module configured to test voltage of a wire;
a load testing module;
a voltage comparison module; and
a memory device storing executable code that, when executed, causes the at least one processor to:
test, via the voltage testing module and while the probe tip is in contact with the wire, an unloaded voltage of the wire;
receive a selection indicating whether the wire is to be tested via a positive load test or a negative load test;
apply, via the load testing module, a resistive load to the wire;
test, upon application of the resistive load, a loaded voltage of the wire;
compare, via the voltage comparison module, the tested unloaded voltage to the tested loaded voltage to determine whether a voltage change exists;
determine, based on comparing the voltage change to a predetermined threshold, whether the integrity of the wire is compromised; and
display, via the user interface of the electrical diagnostic device, an indication of whether the integrity of the wire is compromised.

11. The apparatus of claim 10. wherein the wire is initially non-energized and based on the selection indicating the wire is to be tested via the positive load test the testing of the unloaded voltage includes inputting, via the electrical diagnostic device, voltage to the wire to energize the wire and the resistive load is applied simultaneously to the electrical diagnostic device inputting the voltage to the wire in order to perform the testing of the loaded voltage.

12. The apparatus of claim 11, wherein the voltage change for the positive load test is a voltage drop.

13. The apparatus of claim 10, wherein the loaded voltage to the wire is input based on receiving an indication that a toggle switch located on a front face of the electrical diagnostic device has been toggled to a positive voltage and the resistive load is applied based on receiving a signal that a button located on a back face of the electrical diagnostic device has been selected, the button corresponding to the positive load test, the button being selected while the toggle switch has been toggled.

14. The apparatus of claim 10, wherein the wire is energized and based on the selection indicating the wire is to be tested via the negative load test the unloaded voltage of the wire is 0 V.

15. The apparatus of claim 14, wherein the indication of whether the integrity of the wire is compromised indicates confirmation the integrity of the wire is compromised based on the voltage change being different than the unloaded voltage due to the change to the predetermined threshold being the 0 V.

16. The apparatus of claim 14, wherein the loaded voltage to the wire is input based on receiving an indication that a toggle switch located on a front face of the electrical diagnostic device has been toggled to a negative voltage and the resistive load is applied based on receiving a signal that a button located on a back face of the electrical diagnostic device has been selected, the button corresponding to the negative load test, the button being selected while the toggle switch has been toggled.

17. The apparatus of claim 10, wherein the unloaded voltage of the wire is tested upon completion of testing continuity of the wire, wherein testing the continuity of the wire indicates whether the wire is part of an open circuit or closed circuit.

18. The apparatus of claim 10, wherein the testing of the unloaded voltage and the testing of the loaded voltage are performed while the electrical diagnostic device is electrically coupled to a battery of a vehicle.

19. A electrical diagnostic kit, the kit comprising:
an electrical diagnostic device;
electrical connectivity wiring to electrically couple to the electrical diagnostic device to a power source;
a probe tip to be electrically coupled to the electrical diagnostic device and to contact a wire to be tested; and
an auxiliary ground lead;
wherein the electrical diagnostic device includes:
a processor; and
a memory device storing executable code that, when executed, causes the processor to:
test, via a voltage testing module and while the probe tip is in contact with the wire, an unloaded voltage of the wire;
receive a selection indicating whether the wire is to be tested via a positive load test or a negative load test;
apply a resistive load to the wire;
test, upon application of the resistive load, a loaded voltage of the wire;
compare the tested unloaded voltage to the tested loaded voltage to determine whether a voltage change exists;
determine, based on comparing the voltage change to a predetermined threshold, whether the integrity of the wire is compromised; and
display, via a user interface of the electrical diagnostic device, an indication of whether the integrity of the wire is compromised.

20. The electrical diagnostic kit of claim 19, wherein the testing of the unloaded voltage and the testing of the loaded voltage are performed while the electrical diagnostic device is electrically coupled to a battery of a vehicle.
* * * * *
